(19) United States
(12) Patent Application Publication
(10) Pub. No.: US 2023/0019165 A1
(43) Pub. Date: Jan. 19, 2023

(54) SOLAR PANEL WINDOW SHADE DEVICE AND SYSTEM

(71) Applicant: Visionary Enterprises LLC, Brookfield, WI (US)

(72) Inventor: Michael Baudo, Brookfield, WI (US)

(21) Appl. No.: 17/867,634

(22) Filed: Jul. 18, 2022

Related U.S. Application Data
(60) Provisional application No. 63/223,520, filed on Jul. 19, 2021.

(51) Int. Cl. E06B 9/70; E06B 9/42; H02S 30/20; H01L 31/046; H02S 20/26

(52) U.S. Cl. CPC E06B 9/70; E06B 9/42; H02S 30/20; H01L 31/046; H02S 20/26; E06B 2009/2476

(57) ABSTRACT

A solar panel shade system includes a shade tube, a solar panel shade coupled to the shade tube comprising a solar panel film material, a motor coupled to the shade tube to cause the shade tube to rotate to retract or deploy the solar panel shade, and a processing circuit. The processing circuit includes a processor configured to control operation of the motor and a memory storing instructions for the operation of the motor.

### CROSS-REFERENCE TO RELATED APPLICATION PAPERS

This application claims the benefit of and priority to U.S. Provisional Patent Application No. 63/223520, filed Jul. 19, 2021, which is hereby incorporated by reference in its entirety.

### BACKGROUND

The present invention relates generally to the field of solar panels used in conjunction with a window treatment, and more particularly to a solar panel window shade.

Commercial and residential buildings typically utilize window shades to cover windows that are subject to sunlight and, in much lower levels, moonlight. Window shades are typically used throughout the day to minimize heat gain, sun exposure, and glare. The light blocked by a window shade can be converted into electrical energy using photovoltaic cells in solar panels for local energy generation to provide or augment power to the building and increase energy efficiency.

### BRIEF DESCRIPTION OF THE DRAWINGS

FIG. 1 is a front perspective view of a solar window shade according to an exemplary embodiment.

FIG. 2 is a rear perspective view of the window shade of FIG. 1, according to an exemplary embodiment.

FIG. 3 is a top perspective view of a flexible solar panel that may be attached to the solar window shade of FIG. 1 and FIG. 2, according to an exemplary embodiment.

FIG. 4 is a schematic view of the solar window shade of FIG. 1 electrically coupled to a battery system.

FIG. 5 is a side perspective of the torsion spring design of FIG. 4.

FIG. 6 is an isometric view of the 48V motor of FIG. 4 and its components.

### DETAILED DESCRIPTION

Referring to the figures generally, a solar panel window shade device and system are provided herein. According to the present disclosure, a window shade is constructed of one or more flexible solar panels. In an exemplary embodiment, the window shade is used to harvest solar energy to be used for providing power to a building, and is configured to maximize solar utilization while maintaining an inhabitant's view out the window as much as possible.

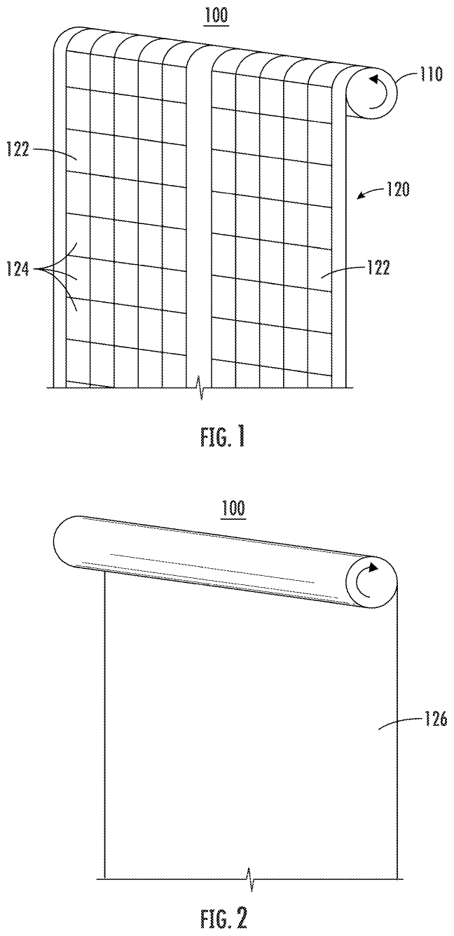

Referring to FIGS. 1 and 2, a solar shade system 100 includes a retractable roller shade having a shade tube 110 carrying a solar panel shade 120. The solar panel shade 120 is made of a solar film material. According to the embodiment shown, the solar panel shade 120 is constructed entirely of the solar film material. In some embodiments, the solar film material is laminated by a translucent material, such as a lightweight and flexible polymer material. In other embodiments, a solar film material may be mounted on a shade backing material, such as by bonding, printing, pressing, adhering, or embedding. The shade backing material may be a fabric material. The solar film material is positioned to face outwardly from a building, towards the sunlight. In other embodiments, however, the solar film material may face an artificial source that may be inside the building. In some embodiments, the solar film material may be placed on both sides of the shade so as to face sunlight and an artificial source of light inside the building. The solar panel shade 120 may be positioned on the inside or the outside of a building. The window provides a barrier that protects the solar panel window shade device 120 from humidity. Further, the thermal gains created by trapping heat in between the glass of a window pane and the solar panel window shade device increases heat retention and absorption by the device.

Solar panel shade 120 is coupled to shade tube 110. The shade tube 110 and solar panel shade 120 are configured such that solar panel shade 120 is retracted (e.g., rolled around shade tube 110) when shade tube 110 is rotated in a first direction and solar panel shade 120 is deployed (e.g., rolled off of shade tube 110) when shade tube 110 is rotated in a second direction, represented by the arrow in FIGS. 1 and 2.

As shown in the view of FIG. 1, solar panel shade 120 includes two elongated solar panels 122. Each solar panel 122 includes a plurality of photovoltaic cells 124. These solar panels may be separated by a seam structure (402 shown in FIG. 4). The number of solar panels 122 making up the solar panel shade 120 is dependent on the size of the solar panel 122 and the size of the window on which the solar shade system 100 is being used. For example, in the embodiment shown having two solar panels, the window size is assumed to be a standard size window, approximately 48-52 inches in width. Therefore, a solar panel shade 120 to fit such a window may require one or more solar panels that are approximately 15 inches or 30 inches wide, using these standard solar panel sizes as an example. Furthermore, additional solar panels 122 positioned longitudinally aligned (not shown) may be necessary to make up an adequate length for the solar panel shade 120. The wires from each solar panel 122 must be integrated within the solar panel shade 120 to transmit the harvested energy through the solar panel shade system 100. The relatively flat arrangement of solar panels 122 on a shade backing 124 reduces shelf shading among solar panels 122. In this way, the solar panels 122 on solar panel shade 120 do not cast shade on one another as the sun moves throughout the day.

In exemplary embodiments in which the solar panel shade 120 is made up of a plurality of solar panels 122, the solar panels 122 do not overlap, but rather are directly adjoined at their edges using a heat-resistant adhesive. In an exemplary embodiment, the heat-resistant adhesive is an adhesive that forms a mesh, such as a spray adhesive. A spray adhesive may harden and provide additional strength as it is exposed to heat.

In other exemplary embodiments, solar panel shade 120 is an accordion style shade (not shown). An accordion style solar panel shade system may consist of a horizontal bi-fold shade backing coupled to a compilation of longitudinally aligned solar panels 122. In other embodiments, the shade system may consist of a vertical bi-fold shade backing coupled to a compilation of laterally aligned solar panels 122.

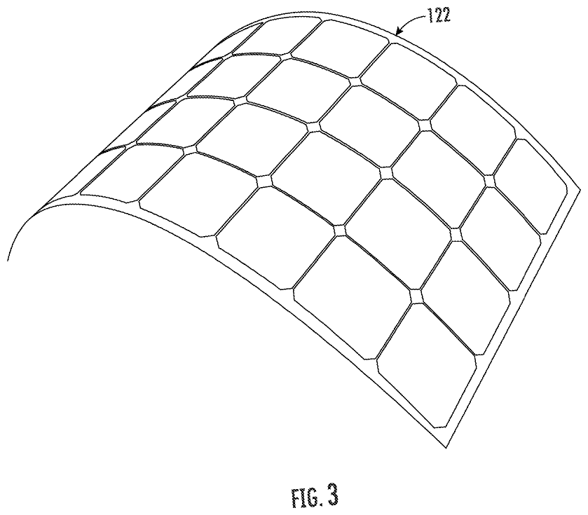

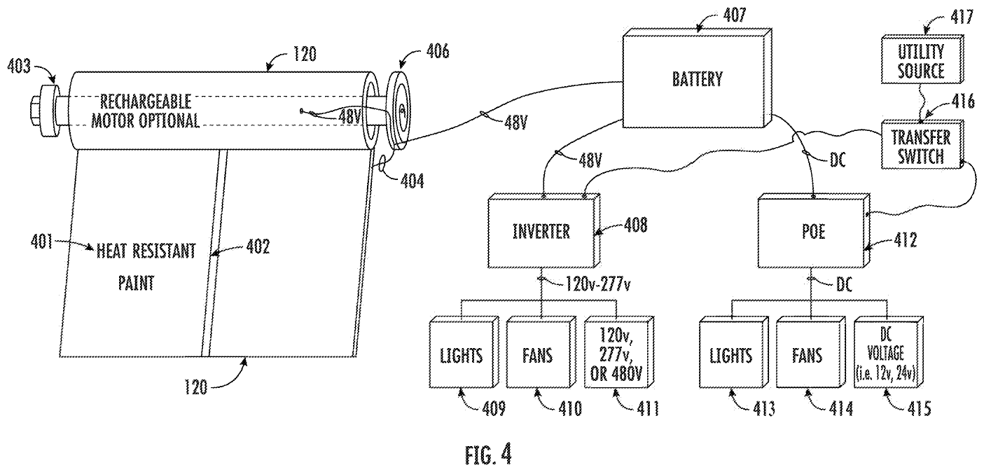

Referring now to FIG. 3, showing an isometric view of solar panel 122 of FIG. 1. In an exemplary embodiment, solar panel 122 may be a flexible solar panel. Solar panels 122 may be of a variety of types, including but not limited to, silicon/crystalline panels, thin-film panels, or organic cell panels. In some embodiments, a combination of types of solar panels 122 may be arranged on solar window panel 120. In other embodiments, the same type of solar panels 122 may be arranged on solar window panel 120.

Typically, a solar panel 122 is black or other dark color. Accordingly, the inner facing surface 126 (shown in FIG. 3) also has this dark color, which may not provide a preferred aesthetic for the inside of the building in which the solar panel shade system 100 is used. For this reason, as well as to assist with retaining the heat at the solar panel(s) 122, the back surface 126 may be covered with a heat resistant paint (401, shown in FIG. 4). In some exemplary embodiments, the heat-resistant paint is a ceramic paint. Ceramic paint may increase the amount of energy generated by solar panels 122 by trapping heat between the glass and the solar panel in addition to assisting with heat retention in the solar panels 122 themselves. In other exemplary embodiments, the heat-resistant paint is an aluminum paint. The paint not only prevents heat from dissipating quickly, but also can provide the back surface 126 with a color, design, pattern, or other aesthetically pleasing appearance. Additionally, the heat resistant paint may support passive cooling of the solar panels 122.

According to an exemplary embodiment, solar panel shade system 100 includes a processing circuit. The processing circuit may include a processor configured to control operation of solar panel shade system 100 and a memory. The memory may, for example, store usage information or instructions for operation of solar panel shade system 100. For example, the memory may store instructions for causing the processor to operate the motor for retracting and deploying the solar panel shade 120. The solar panel shade system 100, namely the motor for deploying and retracting the solar panel shade 120, is controlled by a processor. In an exemplary embodiment, the processor has an open protocol to be used with any control system which is already present in the building or of a user's choosing, for example, a building automation system. In other examples, the solar panel shade system 100 can by controlled by radio, Bluetooth, Dali, 0-10v, Wi-Fi, ZigBee, etc.

As discussed above, the processor is configured to control operation of the solar panel shade system 100, namely for operation of the motor for retracting and deploying the solar panel shade 120. The retraction and deployment of the solar panel may be based on a protocol that simultaneously makes most efficient use of the solar energy while minimizing obstruction of an inhabitants view. In this way, the solar panel shade system 100 is an automated system which controls solar panel shade 120. In some embodiments, the automatic control is based on the direction which the building window faces (for example, in North America, windows facing east, south, or west are preferred windows for utilizing the system to capture the solar energy most effectively). Furthermore, the automatic control is based on the location of the building, particularly, utilizing global positioning and the angle of incidence from the sun (current or a yearly average) to develop an automated plan for retracting and deploying the solar panel shade 120. In a preferred embodiment, the automated plan does not simply control the solar panel shade 120 to be fully deployed or fully retracted, but adjusts the level of the solar panel shade 120 based on the inputs discussed above (facing, global positioning, angle of incidence) or additional inputs. As an example, an additional input to the processor may be provided by an occupancy sensor which sends a signal and causes the processor to completely lower the solar panel shade 120 (or lower it to the lowest required level) when no one is present in a room. In this way, the system 100 maximizes its ability to harvest the solar energy. In another example, the system may be programmed to assume that a person in an office is typically seated. Therefore, the solar panel shade 120 may be lowered to block and harvest solar energy coming in from a high angle, but not to block the view closer to the ground of the individual sitting in the room. In another example, the solar panel shade 120 may be controlled based on a time of day, to maximize capture based on the angle of the sun, or be lowered throughout the night (when shades are very often not lowered) to capture the energy from the moonlight, though minimal. Other control inputs, settings, and features may be implemented in the system 100 in order to optimize use of the solar energy while also not fully blocking the view of an inhabitant. According to an exemplary embodiment, the retraction or deployment of the solar panel shade 120 is not based on a signal from a light sensor, as is the case with typical automated solar panel systems.

Referring now to FIG. 4, a solar panel shade 120 is electrically coupled to a system to transmit the power for use. The photovoltaic cells contained in solar panels 122 (shown in FIG. 1) collect energy from photons produced by sunlight. When the sunlight shines on solar panels 122, electrons flow through the photovoltaic cells of solar panels 122 to generate Direct Current (DC) electricity. In an exemplary embodiment, solar panels 122 are directly wired via wire 404 to motor 403 and battery 407. In some embodiments, the DC power generated by the solar panels 122 is transmitted through the battery 407 to inverter 408 where it may be converted into alternating current (AC) power. The AC power can then be used by the building or sent to the electric grid. In an exemplary embodiment, the AC power can be used by lights 409, fans 410, or other powered devices 411. The inverter 408 may be connected to a transfer switch 416 and utility source 417, which may be connected to a power over Ethernet (PoE) device 412. This allows for the AC power to be used by a separate DC power system. In other embodiments, the DC electricity collected from solar panel shade 120 may flow through wire 404 to battery 407 which may transmit the electricity directly to POE device 412. In this regard, the DC power system may power lights 413, fans 414, and other devices 415. In an exemplary embodiment, the DC power is utilized in a building having an internal rechargeable battery system 407 which is used in turn to power other battery powered devices 415 such as computers, cell phones, tablets, battery-operated cars, lights, etc. In such cases, the efficiency of the solar panel shade system 100 provides extremely efficient power production for the building by eliminating the losses caused by converting the DC power to AC power, and then back to DC power for these battery-operated devices. Furthermore, local energy generation is significantly more efficient than central generation and distribution (such as from a central energy grid) due to efficiency losses during transmission.

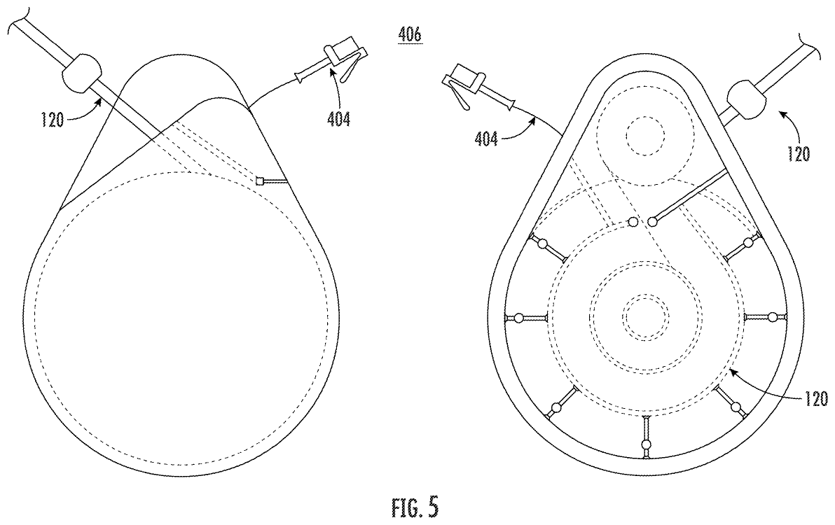

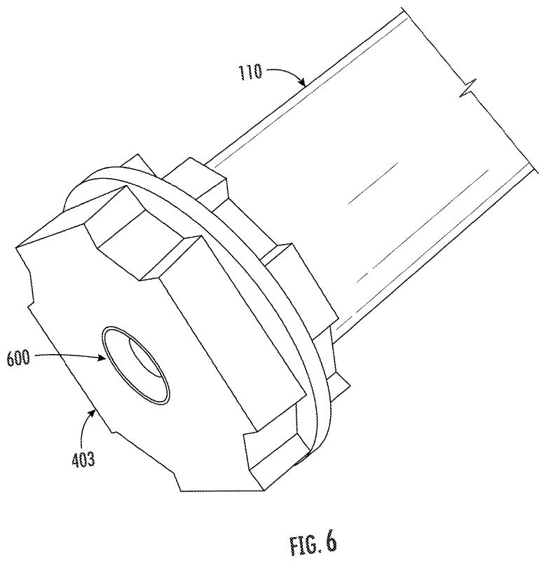

Referring now to FIG. 5, a side view of a torsion spring design 406 used to assist with lifting solar panel shade 120. The use of torsion spring design 406 in conjunction with the motor 403 of FIGS. 4 and 6 reduces the power required by the motor to lift/retract the shade 120. Shade 120 is may be rolled up and housed in shade tube 110 as shown in FIG. 5. Wire 404 may also be rolled up with shade 120, this prevents wire 404 from becoming tangled. According to an exemplary embodiment, solar panel shade 120 is deployed or retracted using a low voltage DC motor coupled to shade tube 110. Furthermore, the solar panel shade system 100 utilizes a torsion spring to assist with lifting solar panel shade 120, to reduce the power required by the motor to lift/retract shade 120. The low voltage DC motor provides sufficient power to lower the shade with the help of gravity and wind the torsion spring. Then, the low voltage DC motor and the torsion spring work together to lift the shade.

Referring now to FIG. 6, an isometric view of a motor mechanism coupled to shade tube 110 that connects the motor mechanism to the torsion spring of FIG. 5. In an exemplary embodiment, the motor 403 creates excess torque by rotating shade tube 110 counter clockwise. In this way, the motor winds the torsion spring of FIG. 5 which in turn aids the motor in lifting solar panel shade 120 up. In this way, solar panel shade system 100 according to an exemplary embodiment, reduces the energy required by the motor and the motor size required for manipulating solar panel shade 120. In some embodiments, the motor 403 may be a rechargeable motor. If motor 403 is a rechargeable motor, the motor mechanism may include charging port 600 which may be connected to a separate power source occasionally in order to charge motor 403.

The foregoing description relates to use of a solar panel window shade system 100 used in a building. However, a similar system may be used in other structures such as gazebos, pavilions, tents, boats, recreational vehicles, etc. Furthermore, a similar technology may be implemented on a building awning or louvers.

The embodiments described herein have been described with reference to drawings. The drawings illustrate certain details of specific embodiments that implement the systems, methods, and programs described herein. However, describing the embodiments with drawings should not be construed as imposing on the disclosure any limitations that may be present in the drawings.

The present invention is not limited to the particular methodology, protocols, and expression of design elements, etc., described herein and as such may vary. The terminology used herein is for the purpose of describing particular embodiments only and is not intended to limit the scope of the present invention.

As used herein, the singular forms include the plural reference and vice versa unless the context clearly indicates otherwise. The term “or” is inclusive unless modified, for example, by “either.” For brevity and clarity, a particular quantity of an item may be described or shown while the actual quantity of the item may differ. Other than in the operating examples, or where otherwise indicated, all numbers expressing measurements used herein should be understood as modified in all instances by the term “about,” allowing for ranges accepted in the art.

Unless defined otherwise, all technical terms used herein have the same meaning as those commonly understood to one of ordinary skill in the art to which this invention pertains. Although any known methods, devices, and materials may be used in the practice or testing of the invention, the methods, devices, and materials in this regard are described herein.

The foregoing description of embodiments has been presented for purposes of illustration and description. It is not intended to be exhaustive or to limit the disclosure to the precise form disclosed, and modifications and variations are possible in light of the above teachings or may be acquired from this disclosure. The embodiments were chosen and described in deposit to explain the principals of the disclosure and its practical application to enable one skilled in the art to utilize the various embodiments and with various modifications as are suited to the particular use contemplated. Other substitutions, modifications, changes and omissions may be made in the design, operating conditions and arrangement of the embodiments without departing from the scope of the present disclosure.

What is claimed is:

1. A solar panel shade system, comprising:
a shade tube;
a solar panel shade coupled to the shade tube, the solar panel shade comprising a solar panel film material;
a motor coupled to the shade tube to cause the shade tube to rotate to retract or deploy the solar panel shade; and
a processing circuit comprising:
a processor configured to control operation of the motor and a memory storing instructions for the operation of the motor.

2. The solar panel shade system of claim 1, wherein the solar panel shade comprises the solar panel film material attached to a shade material.

3. The solar panel shade system of claim 1, wherein the solar panel film material is laminated.

4. The solar panel shade system of claim 1, wherein the solar panel film material comprises at least one of: silicon/crystalline panels, thin-film panels, or organic cell panels.

5. The solar panel shade system of claim 1, wherein the solar panel shade comprises at least two solar panels.

6. The solar panel shade system of claim 1, wherein the solar panel film material is attached to the solar panel shade using a heat-resistant adhesive.

7. The solar panel shade system of claim 1, wherein a back surface of the solar panel shade includes a heat-resistant paint.

8. The solar panel shade system of claim 7, wherein the heat-resistant paint is a ceramic paint or aluminum paint.

9. The solar panel shade system of claim 1, wherein the motor is a low voltage DC motor.

10. The solar panel shade system of claim 9, further comprising a torsion spring to be used in conjunction with the DC motor to retract the solar panel shade.

11. The solar panel shade system of claim 1, wherein the motor is a rechargeable motor that includes a charging port.

12. The solar panel shade system of claim 1, wherein the processor is configured to control the motor to manipulate the solar panel shade based on at least one of: direction of window facing, global positioning of the building, angle of incidence of the sun, time of day, or a combination thereof.

13. The solar panel shade system of claim 1, further comprising an occupancy sensor, wherein the processor is configured to control the motor to manipulate the solar panel shade based on occupancy of a room.

14. The solar panel shade system of claim 1, wherein the solar panel shade can be positioned on the inside or the outside of a building window.

15. A method for generating energy using a solar window shade, the method comprising:
coupling a window shade to a solar panel film material and a shade tube;
connecting the window shade to a motor and a system for transmitting power;
deploying the window shade from the shade tube using at least a motor or a torsion spring coupled to the shade tube;
directing a face of the solar panel film material towards a source of light; and
retracting the window shade using at least the motor or the torsion spring.

16. The method of claim 15, wherein the solar window shade is controlled by a processing circuit configured to operate the motor and memory storing instructions for the operation of the motor.

17. The method of claim 15, wherein the processor controls the motor to manipulate the solar panel shade based on at least one of: direction of window facing, global positioning of the building, angle of incidence of the sun, time of day, or a combination thereof.

18. The method of claim 15, wherein the processor is in communication with an occupancy sensor, and controls the motor to manipulate the solar panel shade based on occupancy of a room.

19. The method of claim 15, wherein the power system comprises a battery connected to an inverter and a power over Ethernet device.

20. The method of claim 19, wherein the inverter is connected to a transfer switch capable of switching AC power to DC power, the transfer switch being further connected to the power over Ethernet device.
